(19) United States
(12) Patent Application Publication
(10) Pub. No.: US 2010/0218989 A1
(43) Pub. Date: Sep. 2, 2010

(54) Connector Module For A Door Actuator

(75) Inventors: Holger Hänsch, Witten (DE); Alexander Hellwig, Ennepetal (DE); Michael Hufen, Wuppertal (DE)

Correspondence Address: COHEN, PONTANI, LIEBERMAN & PAVANE LLP, 551 FIFTH AVENUE, SUITE 1210, NEW YORK, NY, 10176, US

(73) Assignee: DORMA GMBH + KG, ENNEPETAL (DE)

(21) Appl. No.: 12/741,498

(22) PCT Filed: Nov. 6, 2008
(86) PCT No.: PCT/EP08/09340

§ 371 Date: May 5, 2010

(30) Foreign Application Priority Data
Nov. 13, 2007 (DE) 10 2007 054 463.6

(51) Int. Cl. H05K 5/02

(52) U.S. Cl. 174/559

(57) ABSTRACT

A door operator with at least one base element, a first and a second front element and two lateral elements, the base, front, and lateral elements being interconnected and at least one of the elements being configured with a breakthrough for the passage of electrical connecting elements. At least one of the base, front, and lateral elements is disposed at the base element to be foldable.

### PRIORITY CLAIM

This is a U.S. national stage of application No. PCT/EP2008/009340, filed on Nov. 6, 2008 which claims priority to the German Application No.: 10 2007 054 463.6, filed: Nov. 13, 2007, the content of both incorporated herein by reference.

### BACKGROUND OF THE INVENTION

1. Field of the Invention

The present invention relates to a connector module for a door operator with at least one base element, a first and a second front element and two lateral elements, the elements being interconnected and at least one of the elements being configured with a breakthrough for the passage of an electrical connecting element, which may comprise electrical conductors, control cables, or the like.

2. Related Art

Electrical connector boxes to connect electrical conductors are generally known in the state-of-the-art, wherein these connections are accommodated within the connector box in an electrically insulated manner. Utility Model DE 20 2005 008 385 U1 discloses a cuboid, electrical connector and junction box, which is closable via a cover. In reality such boxes have proven to be difficult to close with the cover, if many and/or long electrical conductors are accommodated within the box. Moreover, the connection of the electrical conductors is practically very often difficult and expensive, because only one access to the connector box via the opening in the box is possible, which is closed by the cover.

An electrical connector box closable with a cover is likewise known from DE 196 04 564 C1. In this case, the connector box has a cuboid body, wherein the cover not only closes a lateral opening, but extends over almost three sides. Thus, when connecting the electrical conductors, three open sides of the connector box are accessible, which sides are closable by the correspondingly moulded cover, once the connections are established. A simpler manipulation of the connector box when establishing the connection is hereby possible. However, it is disadvantageous that too many and/or long electrical conductors can be pinched and damaged by the cover to be installed.

Connector modules of the above mentioned species serve to receive electrical connecting elements, such as electrical conductors, electrical cables, and electrical terminals, which are necessary to operate a door operator and/or closing operator. The aforementioned door and/or closing operators for doors serve to automatically open and/or close a door, a window or the like. For the purpose of simplification, in the following description, only the term door operator will be used, this term comprises likewise closing operators, respectively closing elements. In this case, the connector module may be provided within a housing of the door operator. It is likewise conceivable that the connector module itself represents a portion of the housing of the door operator. Usually, connector boxes of the aforementioned species are utilized as the connector modules. During installation or service work on the door operator, the shock-proof shielding of the connector module is momentarily neutralized, to allow for access to the electrical connecting elements within the connector module. In this case, the same issues already mentioned in conjunction with the connecting boxes may occur.

### SUMMARY OF THE INVENTION

It is an object of the present invention to provide a connector module for a door operator, which offers a cost-effective option, to accommodate electrical connecting elements electrically insulated and shock-proof within a door operator and to reduce and simplify the manipulation of the connector module.

According to one embodiment of the invention, at least one of the first and the second front elements and the two lateral elements, is disposed foldably at the base element. This foldable disposition of at least one element at the base element allows on the one side for a large-area access to the electrical connecting elements of the connector module, whereby the manipulation is considerably simplified, in particular when connecting the electrical connecting elements. On the other hand, closing the connector module is easier, because, in the area of the foldable connection between the base element and the hinged element, the connecting elements are reliably prevented from being pinched or from protruding. It is furthermore intended that at one of the elements, for example the first front element, at least one fastening element, in particular two fastening elements are moulded. It is via these fastening elements that the connector module is mechanically and reliably connected to the rest of the door operator, in particular to a mounting plate of the door operator. For this purpose, appropriate counter-fastening elements, which positively and/or non-positively cooperate with the fastening elements of the connector module, are provided at the rest of the door operator.

The electrical connecting elements themselves may be provided with a connector, a plug-and-socket connection, or the like, to simplify the electrical connection. For this purpose, the opening in the connector module is configured appropriately large sized. Usually, the electrical connecting elements are introduced into the connector module via a wall side and are electrically connected at that location via plug-and-socket connections, screw terminals, or the like. The corresponding screw terminals or plug-and-socket connections may be disposed on a connecting unit for this purpose, which is preferably configured as a circuit board. The connecting unit is configured to receive connecting terminals, circuit boards and/or other electrical components or circuit components, such as filters or the like.

Because the at least one element is disposed at the base element is foldable, it can not disappear or be lost like a removable cover can. This element will likewise not fall down when manipulating the connector module. Thus, the one-piece configuration of the connector module additionally simplifies the manipulation. Moreover, such a connector module is cost-effectively manufactured, in particular if it essentially consists of plastic material.

All front elements and/or lateral elements are preferably disposed at the base element to be foldable, which results in a completely free access to the connector module and in a particular easy manipulation. In this case, the structure of the connector module is simplified by a cuboid configuration, because the foldable elements can be joined to form a (closed) housing via their rectangular sides.

According to one embodiment of the invention, the base element is rectangular, in particular flat. The rectangular configuration of the base element benefits a uniformly shaped and functional connection to the door operator. It is advantageous in this case that the electrical clamps, connectors, or the like, for electrically or electronically connecting the door operator, to be incorporated or disposed on the flat surface of the base element, in order to connect the door operator to an external energy supply and/or control.

In a preferred embodiment the base element is configured, at least at one side, with a U-shaped contact surface. The U-shaped contact surface provides a re-enforced reception area for the incoming electrical connecting elements. At the same time, the U-shaped contact surface may serve as an abutment for a foldably configured front element or lateral element. Moreover, it is thus possible to support the entire connector module via the U-shaped contact surface on the correspondingly configured element.

Furthermore, the possibility is given that the first front element, in one terminal position, can be disposed to partially bear against the U-shaped contact surface. It is furthermore conceivable in this case, that the U-shaped contact surface is configured such that the first front element, in the terminal position, can be disposed to be partially located within the U-shaped contact surface. This overlapping support of the first front element within the U-shaped contact surface, in the terminal position, provides a positive reception of portions of the first front element partially within the U-shaped contact surface of the base element.

Advantageously, the breakthrough for the passage of electrical connecting elements, in the terminal position of the first front element, is partially disposed to be congruent with an opening in the U-shaped contact surface. The partially congruent disposition of the breakthrough of the first front element and the opening of the U-shaped contact surface allows the electrical connecting elements to be led into the connector module, wherein the front element may be likewise configured to be foldable with regard to the base element.

In one embodiment of the present invention, the base element be configured with an almost vertically disposed connecting web, at least at one side, in particular at two wide sides with two connecting webs. It is particularly advantageous that the connecting webs are configured uniformly from the same material and integrally with the webs of the U-shaped contact surface. This configuration of the surface of the base element creates a stable base for the disposition of the elements complementing the connector module. Furthermore, the space between the two connecting webs may serve to receive a provided connecting unit, at which the connectors or screw terminals are disposed. In this case, energized components may be disposed between the base element and the connecting unit such that they are not exposed.

Furthermore, the option is given for at least one of the elements, in particular for the base element, to be equipped with at least one retaining device for disposing at least one connecting unit, wherein the connecting unit has a corresponding counter-retaining device. It is possible in this case that, within the base element, the retaining device is configured as a breakthrough which is reversibly and/or non-positively and positively connectable to corresponding clips at the connecting unit.

A particularly cost-effective embodiment of the invention provides that the connector module be configured as an injection moulded part, wherein at least one connection between the base element and the elements at its side has a hinge-type disposition, wherein in particular the front elements are connected to narrow sides and the lateral elements to wide sides in a hinge-type manner. Due to the hinged configuration of the connection between the base element and the front elements, respectively the lateral elements, the connector module remains one piece during the transfer from the terminal position to a basic position. In this case, the lateral elements, respectively the front elements, which, in the terminal position, are disposed almost vertical with regard to the base element, can be folded-down at their location connected to the base element in a direction opposite to their corresponding lateral element, respectively front element.

Furthermore, in one embodiment, the connector module is configured as one piece and uniformly produced from the same material, realized in particular via the connection of one or more elements to the base element by rebated or film hinges. Advantageously the connector module is manufactured from a current-insulating plastic material in an injection moulding process, to keep manufacturing cost low. A configuration of the hinge-type articulation with an axis is likewise conceivable. In this case, in a dual injection moulding process, the axis may be embedded or injected in one process step as a joint pin between the elements of the connector module to be connected.

In a particularly advantageous variant, in the basic position of the connector module, in which all the elements are folded-down, the base element and the respective front element, or lateral element are disposed almost parallel to each other.

Another measure of improvement provides that the connector module, at least at one element, is configured at least partially with reinforcing ribs, and in particular the lateral elements at the inner sides are configured at least partially with reinforcing ribs. It is in particular advantageous, if the reinforcing ribs are configured honeycomb-shaped, because a higher strength of the structure of the lateral elements can be achieved with simultaneous material savings. This is insofar particularly practical, because, when mounting the connector module to the door operator, these elements serve as grip ends, and the additional reinforcement guarantees the shock-proof shielding of the connecting elements located inside the connector module. It is likewise conceivable, that the base element and/or the front element and/or the lateral elements are provided with an electromagnetic shielding, to prevent electronic, respectively electromagnetic interference. The aforementioned elements may be coated with a metal layer for this purpose. It is likewise conceivable to incorporate an appropriate shielding layer within the elements, for example by a wire mesh.

In a further embodiment, the lateral elements are configured with a latch, which, in the terminal position rest in counter-latch, which are configured or at the front elements. It is particularly advantageous if the latch is configured as latching hooks, which positively bear in or against counter-latch configured as a recess. This configuration of the latch and counter-latch, is very easy to realize in an injection moulding process, and allows for a simple transfer of the connector module from the basic position to the terminal position and protects the location of the elements in the terminal position. In this case, it is particularly advantageous, if the latching hooks are integrally configured with the lateral elements.

### BRIEF DESCRIPTION OF DRAWINGS

Further measures improving the invention are indicated or are illustrated in detail in the following, in conjunction with the description of one preferred embodiment of the invention and based on the Figures, in which:

FIG. 1 is a perspective view of a connector module in a basic position II;

FIG. 2 is another perspective view of the connector module in a basic position II;

FIG. 3 is another perspective view of the connector module in a terminal position I with connecting elements, and

FIG. 4 is a perspective view of a door operator with the connector module, without housing.

### DETAILED DESCRIPTION OF THE PREFERRED EMBODIMENTS

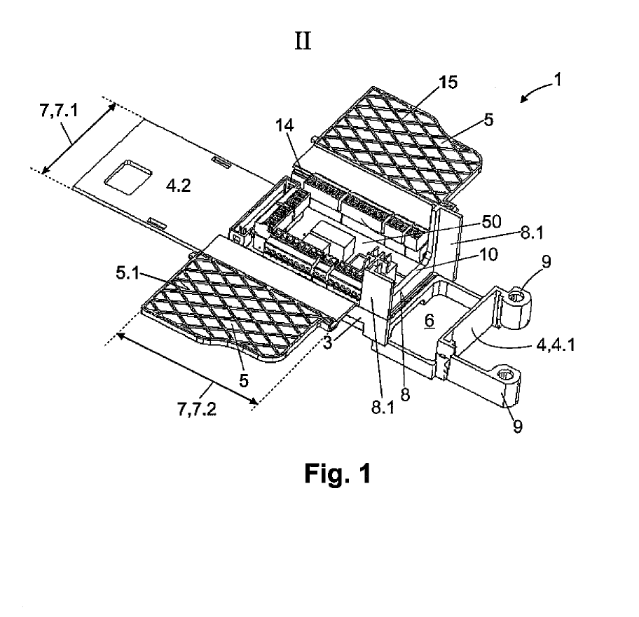

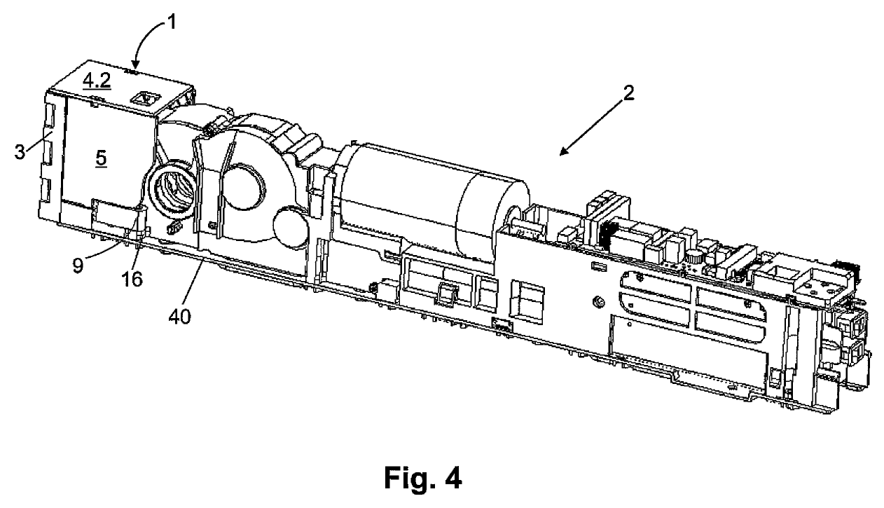

FIG. 1 shows a folded-down connector module 1. The connector module 1 is intended for a door operator 2, which is illustrated by way of example in FIG. 4 without a housing. The connector module 1 is in a basic position II in FIG. 1. Front elements 4, 4.1, 4.2 and the lateral elements 5 are folded-down and are disposed almost parallel to the base element 3. As can be seen, free and easy access to an existing connecting unit 50 is possible, which has screw terminals and plug-and-socket connections, to electrically connect the non-illustrated electrical connecting elements to the door operator 2. The connecting unit 50 is preferably configured as a circuit board, which is releasably mounted to the base element 3 preferably by screws or latches.

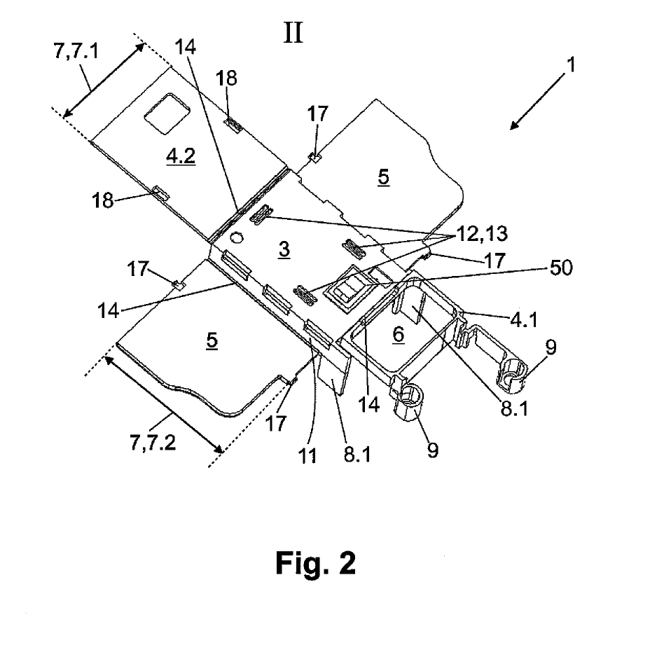

As can be clearly seen in FIG. 2, the base element 3 is rectangular and flat. A U-shaped contact surface 8 of the base element 3 is configured at a narrow side 7.1. Connecting webs 11 are almost vertically disposed to the base element 3 at the wide sides 7.2 of the base element 3. In the area of the U-shaped contact surface 8, the connecting webs 11 are configured as continuing webs 8.1.

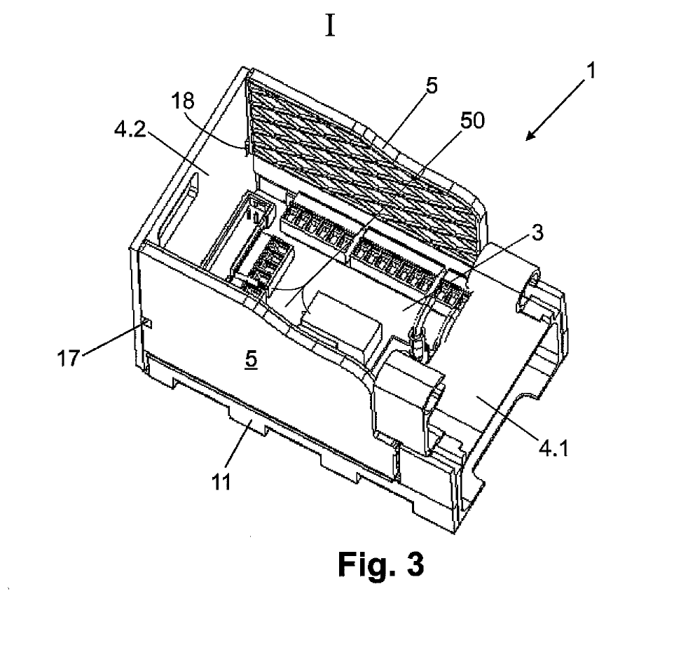

A first front element 4.1, disposed at a narrow side 7.1 of the base element 3, is configured with a breakthrough 6. In a terminal position I, illustrated in FIG. 3, the breakthrough 6 of the first front element 4.1 corresponds to an opening 10, which is configured within the U-shaped contact surface 8 of the base element 3. The access to the connector module 1, resulting therefrom, allows to lead the electrical connecting elements into the connector module 1. In this case, the electrical connecting elements may be provided also with connectors, because the resulting access is configured to be sufficiently large. It is likewise conceivable to provide the breakthrough 6 with a watertight membrane, which allows for a waterproof sealing of the electrical connecting elements which are led therethrough.

The connector module 1 is illustrated from its front side in FIG. 1, such as it might be attached in the basic position II at a door operator 2, to connect the electrical connecting elements to the door operator 2. Once the electrical connecting elements are led through the breakthrough 6, facing the wall, which breakthrough is disposed in the first front element 4.1, a connection of the electrical connecting elements to the connecting unit 50 may be established. Subsequently, the two lateral elements 5 can be folded up, wherein they are then orthogonally aligned with the base element 3 and prolong the connecting webs 11 over a large area (see FIGS. 3 and 4).

The second front element 4.2 can be folded up in a next step, such as to be likewise orthogonally aligned with the base element 3. A box with four sides and an orthogonal base surface is essentially created thereby. Finally, the entire base element 3, with the folded-up elements 4.2 and 5, is folded against the first front element 4.1, whereby the terminal position I is achievable, which is shown in FIGS. 3 and 4. In the terminal position I, all electrical connecting elements are accommodated electrically insulated and shock-proof within the connector module 1. Moreover, the aforementioned folding movements will not pinch the electrical connecting elements and in addition they are easy to accommodate in the connector module 1. Depending on the configuration of the door operator 2, the connector module 1 may be covered or closed with a housing. It is obvious that, for performing maintenance or repair work or the like for example, the connector module 1 may be transferred from the terminal position I into the basic position II in an order, which is reversed to the above described order.

For attaching the connector module 1 to the door operator 2, a mounting plate 40, preferably two attachment elements 9 are disposed at the first front element 4.1. In this embodiment, the attachment elements 9 are cylindrically shaped and, at their side facing the U-shaped contact surface 8, they have an almost circular breakthrough. Screws may be already pre-mounted in the attachment elements 9 to screw the connector module 1 tightly to the door operator 2, respectively the mounting plate 40. The first front element 4.1 is configured in webs. In the terminal position I, the first front element 4.1 is partially disposed as bearing against the U-shaped contact surface 8.

FIG. 4 shows how the connector module 1 is attachable to and releasable from the counter-attachment elements 16, which correspond to the attachment elements 9, by screws on a mounting plate 40 of the door operator 2. For this purpose, appropriate threads, respectively nuts for the screws may be present in the counter-attachment elements 16.

In FIG. 1, the reinforcing ribs 15 are visible at the inner sides 5.1 of the lateral elements 5. The honeycomb-shaped structure of the reinforcing ribs 15 represents a particular material-saving manner to reinforce the structure of an element 3, 4, 5. In the present case, the connections between the elements 3, 4, 5 are executed as film hinges 14. The lateral elements 5 are disposed at the base element 3 via connecting webs 11.

In a terminal position I, illustrated in FIG. 3, the front elements 4.1, 4.2 and the lateral elements 5 are disposed almost vertical to the base element 3. In this case, the breakthrough 6 in the first front element 4.1 is disposed almost congruent to the opening 10 of the U-shaped contact surface 8. This guarantees passing the electrical connecting elements through into the connector module 1.

In the connector module 1, illustrated in a basic position II in FIG. 2, the retaining elements 12 are configured as breakthroughs within the base element 3. In this case, the breakthroughs 12 are configured as oblong double breakthroughs 12, which are disposed parallel to each other. The breakthroughs 12 correspond to clip-like configured counter-retaining elements 13, which are disposed at the connecting unit 50 and allow for fastening the connecting unit 50 on the base element 3.

Furthermore, the latches 17 are visible in FIG. 2, which are moulded at the lateral elements 5 and the base element 3. The latches 17 are configured as latching noses, which, in the terminal position I illustrated in FIG. 3, can be disposed positively and/or non-positively in or at corresponding counter-latching elements 18 of the front element 4 or the base element 3.

At the second front element 4.2, counter-latching elements 18 are configured as breakthroughs 18 for receiving the corresponding latches 17 of the lateral elements 5. At the side of the web 8.1 facing the U-shaped contact surface 8, the base element 3 is executed with a contact surface 18, configured as a counter-latching element 18, against which, in the terminal position I, the latches 17 bear under tension.

FIG. 3 shows the connector module 1 in the terminal position I. It is illustrated in this case that the elements 4 and 5 are disposed almost vertical to the base element 3. In the terminal position I, the latches 17, disposed at the lateral elements 5, are connected to the counter-latches 18 at the front elements 4, respectively at the base element 3, whereby a more stable union of the connector module 1 with its front and lateral elements 4 and 5 is achievable in the terminal position I.

FIG. 4 illustrates the door operator 2 with the mounted connector module 1 in the terminal position I. In this position the electrical connecting elements are electrically insulated and shock-proof disposed inside the connector module 1. In this case, the entire connector module 1 is configured to be open at the right side, wherein this side is closed by further structural components of the door operator 2. In the terminal position I, the base element 3 is essentially disposed vertical to the mounting plate 40 of the door operator module 2. The base element 3 itself may represent a front surface of the door operator 2 in this terminal position I. Usually, the door operator 2 is closed by an essentially U-shaped housing. In the present example, the entire connector module 1 may be screwed to the mounting plate 40 at the counter-attachment elements 16 via the attachment elements 9. When performing maintenance work or the like, the connector module 1 may be transferred from the terminal position I to the basic position II, by folding to the left the base element 3 together with the associated front elements 4 and the lateral elements 5, namely from the vertical position into the horizontal position. Subsequently, the individual elements 4, 5 can be likewise folded away from the base element 3, in order to allow the optimum access to the electrical connecting elements and, if required, to the connecting unit 50.

Instead of or in addition to the above described attaching, respectively mounting the connector module 1 to the door operator 2, latching connections may be provided, which are configured for example analogously to the latching connections described above in conjunction with the connecting unit 50 and the base element 3.

As an alternative, pure clamping attachments can be provided such that there are no particular attachment devices neither at the connector module 1 nor at the door operator 2.

As an alternative, it may be provided to permanently mount the connector module 1 to the door operator 2 by a rivet connection, welding, or glueing.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-24. (canceled)

25. A connector module for a door operator configured to be mountable on a mounting plate of a door operator, comprising:
at least one base element;
a first and a second front element each coupled to the base element by a respective edge;
two lateral elements configured to be arranged substantially parallel to each other and substantially perpendicular to the first and the second front elements, the two lateral elements further configured to be interconnected with the first and the second front elements; and
at least one breakthrough configured to pass through electrical connecting elements in at least one of the first front element, the second front element and the two lateral elements,
wherein at least one of the first front element, the second front element, and the two lateral elements is foldably disposed at the base element.

26. The connector module according to claim 25, wherein the base element is configured as a rectangular and the connector module is cuboid.

27. The connector module according to claim 26, wherein the base element is substantially flat and the connector module is cuboid.

28. The connector module according to claim 25, wherein at least one of the base element and the at least one lateral element is configured with a U-shaped contact surface.

29. The connector module according to claim 28, wherein the first front element at least partially bears against the U-shaped contact surface in a terminal position.

30. The connector module according to claim 29, wherein the breakthrough of the first front element is at least partially congruent with an opening of the U-shaped contact surface in the terminal position of the first front element.

31. The connector module according to claim 25, further comprising at least one attachment element moulded on at least one of the first front elements, the second front element, and the lateral elements.

32. The connector module according to claim 31, wherein at least one attachment element is moulded on the first front element.

33. The connector module according to claim 31, wherein respectively two attachment elements are moulded on at least one of the base, the lateral elements, and the first front element.

34. The connector module according to claim 26, wherein the base element and at least at one lateral element is moulded with a substantially vertically disposed connecting web.

35. The connector module according to claim 34, wherein the base element, is moulded with two substantially vertically disposed connecting webs at its respective two wide sides.

36. The connector module according to claim 25, wherein at least one of the base element, first front element and second first element is provided with at least one retaining element for attaching at least one connecting unit, wherein the connecting unit has a corresponding counter-retaining element.

37. The connector module according to claim 36, wherein the base element is provided with the at least one retaining element.

38. The connector module according to claim 26, wherein the connector module is moulded as an injection moulding part, wherein at least one connection is disposed in a hinge-type manner at one side between the base element and at least one of the front and lateral elements.

39. The connector module according to claim 38, wherein the first and second front elements are connected in a hinge-type manner to narrow sides of the base and the lateral elements are connected in a hinge-type manner to wide sides of the base.

40. The connector module according to claim 39, wherein the connector module is configured as one piece.

41. The connector module according to claim 40, wherein the connection of one or more of the first front element, the second front element and the two lateral elements to the base element is one of a rebated or film hinge and is uniformly made from the same material.

42. The connector module according to claim 25, wherein at least at one of the base, the first front element, the second front elements, and the two lateral elements is configured at least partially with reinforcing ribs.

43. The connector module according to claim 42, wherein the two lateral elements are configured at least partially with reinforcing ribs at respective inner sides facing each other.

44. The connector module according to claim 25, wherein the connector module is configured as being releasably mountable to the mounting plate of the door operator by at least one counter-attachment element, which corresponds to an attachment element.

45. The connector module according to claim 25, wherein the connector module is configured to be permanently disposed on a mounting plate of a door operator.

46. The connector module according claim 25, wherein the two lateral elements are configured with respective latching elements, which, in the terminal position, rest in respective counter-latching elements moulded in the first and second front elements.
